(19) United States
(12) Patent Application Publication
(10) Pub. No.: US 2018/0013033 A1
(43) Pub. Date: Jan. 11, 2018

(54) Light Emitting Diode and Fabrication Method Thereof

(71) Applicant: XIAMEN SANAN OPTOELECTRONICS TECHNOLOGY CO., LTD., Xiamen (CN)

(72) Inventors: Xueliang Zhu, Xiamen (CN); Jie Zhang, Xiamen (CN); Jianming Liu, Xiamen (CN); Chengxiao Du, Xiamen (CN); Chen-ke Hsu, Xiamen (CN)

(73) Assignee: XIAMEN SANAN OPTOELECTRONICS TECHNOLOGY CO., LTD., Xiamen (CN)

(21) Appl. No.: 15/698,631

(22) Filed: Sep. 7, 2017

Related U.S. Application Data
(63) Continuation of application No. PCT/CN2016/097800, filed on Sep. 1, 2016.

(30) Foreign Application Priority Data
Oct. 28, 2015 (CN) 201510708848.4

(51) Int. Cl. H01L 33/06; H01L 33/00; H01L 33/12; H01L 33/32

(52) U.S. Cl. CPC H01L 33/06; H01L 33/325; H01L 33/007; H01L 33/12

(57) ABSTRACT

A light-emitting diode includes a material structure of barrier in the light-emitting well region to improve restriction capacity of electron holes, improving light-emitting efficiency of the LED chip under high temperature. The LED structure includes a Type I semiconductor layer, a Type II semiconductor layer and an active layer between the both, wherein, the active layer is a multi-quantum well structure alternatively composed of well layers and barrier layers, in which, the first barrier layer is a first AlGaN gradient layer in which aluminum components gradually increase in the direction from the Type I semiconductor layer to the quantum well, and the barrier layer at the middle of well layers is an AlGaN/GaN/AlGaN multi-layer barrier layer, and the last barrier layer is a second AlGaN gradient layer in which aluminum components gradually decrease in the direction from the quantum well to the Type II semiconductor layer.

### CROSS-REFERENCE TO RELATED APPLICATIONS

The present application is a continuation of, and claims priority to, PCT/CN2016/097800 filed on Sep. 1, 2016, which claims priority to Chinese Patent Application No. 201510708848.4 filed on Oct. 28, 2015. The disclosures of these applications are hereby incorporated by reference in their entirety.

### BACKGROUND

The GaN-based light-emitting diode (LED), due to its high light-emitting efficiency, has been widely applied in various light source fields such as background lighting, lighting and landscape. As the most important parameter of LED chip, light-emitting efficiency generally refers to the value measured at room temperature of 25° C. A key characteristic of the semiconductor material is that its features change significantly as temperature rises. For example, as temperature rises, the light-emitting efficiency of the LED chip reduces dramatically. When a LED lamp is at work, working environment temperature of the chip is generally above 25° C., particularly in summer or inside lamps with poor heat dissipation. A LED filament lamp, developed recently, has even poorer heat dissipation. Therefore, how to improve light-emitting efficiency of the LED chip under high temperature is a key focus in current epitaxial study.

### SUMMARY

Various embodiments disclosed herein provide a light-emitting diode with improved restriction capacity of electron holes by designing a material structure of barrier in the light-emitting well region, and therefore dramatically improve light-emitting efficiency of the LED chip under high temperature.

In an aspect, a light-emitting diode is provided, including a Type I semiconductor layer, a Type II semiconductor layer and an active layer between the both, wherein, the active layer is a multi-quantum well structure composed of alternative well layers and barrier layers, in which, the first barrier layer is a first AlGaN gradient layer of which aluminum components gradually increase in the direction from the Type I semiconductor layer to the quantum well; the barrier layer at the middle of the well layers is an AlGaN/GaN/AlGaN multi-layer barrier layer; and the last barrier layer is a second AlGaN gradient layer of which aluminum components gradually decrease in the direction from the quantum well to the Type II semiconductor layer.

In some embodiments, the GaN layer of the AlGaN/GaN/AlGaN multi-layer barrier layer is p-type doped. If a small amount of Mg atoms are doped, the injection efficiency of holes under high temperature can be improved.

In some embodiments, in the AlGaN/GaN/AlGaN multi-layer barrier layer, the AlGaN layer is 1-3 nm thick with Al component of 5-20%, and the GaN layer is 1-5 nm thick with p-type doping.

In some embodiments, the first AlGaN gradient layer is 3-15 nm thick, with Al component of 0 at the starting terminal, and Al component of 10-30% at the ending terminal.

In some embodiments, the second AlGaN gradient layer is 3-15 nm thick, with aluminum component of 10-30% at the starting terminal, and aluminum component of 0 at the ending terminal.

According to some embodiments of the present disclosure, the active layer structure greatly improves light-emitting efficiency of the LED chip under high temperature. The energy band of the AlGaN/GaN/AlGaN barrier layer between every two light-emitting quantum wells has higher band offset than that of the single-layer GaN in original structure, and can restrict electron holes in the quantum well in a more effective manner, thus reducing the possibility of electron hole overflow and enabling radioactive recombination in the quantum well, thereby improving light-emitting efficiency; the middle GaN barrier layer, by doping a small amount of Mg atoms, can improve injection efficiency of holes under high temperature, and effectively maintain voltage of the LED chip; meanwhile, the AlGaN layer at both sides of the barrier layer can prevent Mg atoms from expanding to the quantum well, to avoid deep defect energy level of the quantum well due to Mg doping in the barrier layer. While the first AlGaN gradient layer plays an effective role in limiting electrons or holes, it would not be difficult for the electrons in the Type I semiconductor to inject into the quantum well region, as its aluminum component of the first AlGaN gradient layer gradually increases in the direction from the Type I semiconductor to the quantum well. It would not be difficult for the holes in the Type II semiconductor to inject into the quantum well region, as the aluminum component of the second AlGaN barrier layer gradually decreases in the direction from the quantum well to the Type II semiconductor direction.

In another aspect, a fabrication method of an LED is provided, including the following steps: growing a Type I semiconductor layer, an active layer and a Type II semiconductor layer, in which, the active layer is formed with the following steps: 1) growing a first AlGaN gradient layer with gradient aluminum components as the first barrier layer, wherein, the aluminum components are controlled by the trimethylaluminum input to the reaction chamber, where, the trimethylaluminum flow at starting point is 0, and gradually increases during growth; 2) growing a first quantum well layer; 3) growing a middle barrier layer, with a structure of AlGaN/GaN/AlGaN multi-layer barrier layer; 4) repeatedly growing the quantum well layers and the middle barrier layers with n cycles, wherein n>2; and 5) growing a second AlGaN gradient layer with gradient aluminum components as the last barrier layer after growing the last quantum well layer, wherein, the aluminum components are controlled by the trimethylaluminum input to the reaction chamber, where, the trimethylaluminum flow is maximum at the starting point, and gradually decreases during growth.

In some embodiments, the first AlGaN gradient layer formed in step 1) is 3-15 nm thick with Al component of 0 at the starting terminal, and Al component of 10-30% at the ending terminal.

In some embodiments, in the AlGaN/GaN/AlGaN multi-layer barrier layer formed in step 3), the GaN layer is p-type doped.

In some embodiments, in the AlGaN/GaN/AlGaN multi-layer barrier layer formed in step 3), the AlGaN layer is 1-3 nm thick with Al component of 5-20%, and the GaN layer is 1-5 nm thick with p-type doping.

In some embodiments, the second AlGaN gradient layer formed in step 5) is 3-15 nm thick, with aluminum component of 10-30% at the starting terminal, and aluminum component of 0 at the ending terminal.

In another aspect, some embodiments of the present disclosure provide a light-emitting system including a plurality of light-emitting diodes (LEDs), wherein, each LED comprises: a Type I semiconductor layer, a Type II semiconductor layer, and an active layer between the both. The active layer is a multi-quantum well structure alternatively composed of well layers and barrier layers, in which, the first barrier layer is a first AlGaN gradient layer in which aluminum components gradually increase in the direction from the Type I semiconductor layer to the quantum well, and the barrier layer at the middle of well layers is an AlGaN/GaN/AlGaN multi-layer barrier layer, and the last barrier layer is a second AlGaN gradient layer in which aluminum components gradually decrease in the direction from the quantum well to the Type II semiconductor layer.

Other features and advantages of various embodiments of the present disclosure will be described in detail in the following specification, and it is believed that such features and advantages will become more apparent in the specification or through implementations of various embodiments disclosed herein. The purposes and other advantages of the embodiments can be realized and obtained in the structures specifically described in the specifications, claims and drawings.

### BRIEF DESCRIPTION OF THE DRAWINGS

The accompanying drawings, which are included to provide a further understanding of the various embodiments disclosed herein and to constitute a part of this specification, together with the embodiments, are therefore to be considered in all respects as illustrative and not restrictive. In addition, the drawings are merely illustrative, which are not drawn to scale.

FIG. 1 shows a complete structure diagram of an LED according to some embodiments.

FIG. 2 shows an energy gap diagram of an active layer according to some embodiments.

In the drawings:

100: substrate; 110: buffer layer; 120: N-type GaN layer; 130: InGaN/GaN super lattice; 140: active layer; 141: first barrier layer; 142: quantum well layer; 143: middle barrier layer; 1431: first layer of AlGaN/GaN/AlGaN multi-layer barrier layer; 1432: second layer of AlGaN/GaN/AlGaN multi-layer barrier layer; 1433: third layer of AlGaN/GaN/AlGaN multi-layer barrier layer; 144: last barrier layer; 150: P-type electron blocking layer; 160: P-type GaN layer.

### DETAILED DESCRIPTION

Various embodiments of the light-emitting diode structure and fabrication method thereof are described in detail with reference to the accompanying drawings, to help understand and practice the disclosed embodiments, regarding how to solve technical problems using technical approaches for achieving the technical effects. It should be understood that the embodiments and their characteristics described in this disclosure may be combined with each other and such technical proposals are deemed to be within the scope of this disclosure without departing from the spirit of this invention.

Among many causes for lower light-emitting efficiency of a light-emitting diode under high temperature, two are dominant: one is that, nonradioactive recombination process of the semiconductor material increases under high temperature, through which, more electron holes annihilate and generate excessive heat; the other is that, the electron hole pair has increasing energy under high temperature, and is prone to escape from the quantum well light-emitting region of the chip, thus finally reducing effective light-emitting efficiency. On one hand, by improving crystalline quality of the light-emitting region of the LED chip, nonradioactive center can be inhibited to improve low light-emitting efficiency under high temperature. On the other hand, overflow of carriers under high temperature can be inhibited by regulating the energy gap structure of the light-emitting diode, thus increasing proportion of light-emitting carriers.

In an aspect, some embodiments below provide a light-emitting diode for improving light-emitting efficiency under high temperature by designing a material structure of barrier in the light-emitting well region to improve restriction capacity on electron holes. In this way, overflow of carriers under high temperature can be inhibited to improve light-emitting efficiency of LED chips under high temperature.

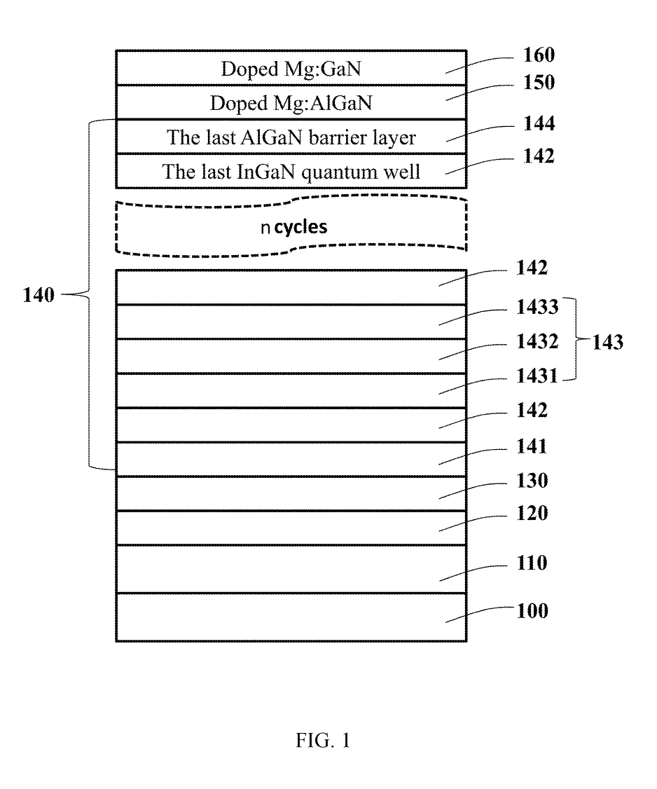

FIG. 1 illustrates an epitaxial structure for improving LED light-emitting efficiency under high temperature, which includes from bottom to up: a substrate 100, a buffer layer 110, an N-type GaN layer 120, an InGaN/GaN super lattice 130, an active layer 140, a P-type electron blocking layer 150 and a P-type GaN layer 160.

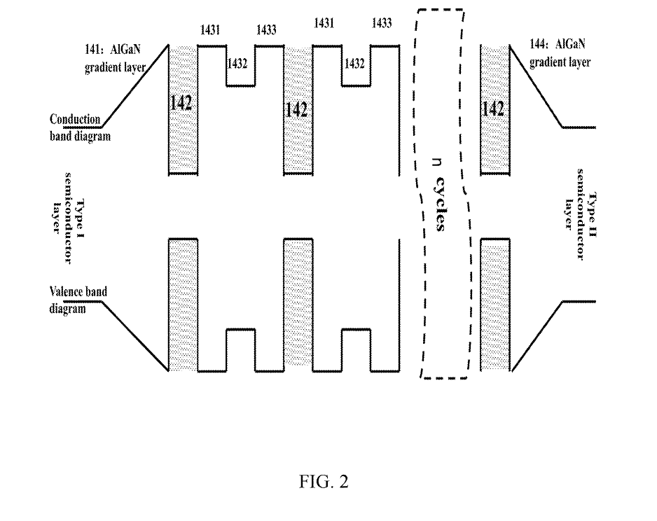

According to some embodiments of the present disclosure, the core is the active layer structure. In some embodiments, the active layer 140 is a multi-quantum well structure, in which, the starting terminal is a first AlGaN gradient layer of which aluminum components gradually increase along the direction from the N-type GaN layer 120 to the quantum well; the ending terminal is a second AlGaN gradient layer of which aluminum components gradually decrease along the direction from the quantum well to the P-type electron blocking layer 150; and the middle are quantum well layers 142 and a middle barrier layer 143 between the quantum well layers 142. FIG. 2 illustrates the energy gap diagram of the active layer. The first AlGaN gradient layer serves as the first barrier layer 141 of the multi-quantum well structure, the second AlGaN gradient layer servers as the last barrier layer 144 of the multi-quantum well structure, and the middle barrier layer 143 is a AlGaN/GaN/AlGaN multi-layer barrier layer. The GaN layer 1432 at the middle is doped with a small amount of Mg atoms to improve injection efficiency of holes under high temperature, and the AlGaN layers at both sides prevent Mg atoms from expanding to the quantum well, to avoid deep defect energy level of the quantum well due to Mg doping in the barrier layer.

Details will be given to the aforementioned epitaxial structure in combination with fabrication method.

First, put the sapphire pattern substrate 100 to a metalorganic chemical vapor deposition (MOCVD) for processing of 3-10 minutes under hydrogen atmosphere by rising temperature to 1,000-1,200° C.;

Next, input ammonia gas and trimethyl gallium, grow a 20-50 nm low-temperature buffer layer 110 by lowering temperature to 500-600° C., and cut off trimethyl gallium;

Next, grow a 1.5-4 μm N-type GaN layer 120 by rising temperature to 1,030-1,120° C.;

Next, grow an InGaN/GaN super lattice layer 130 with 5-25 cycles by lowering temperature to 800-900° C., wherein, the InGaN layer is 1-2 nm thick and the GaN layer is 2-30 nm thick;

Next, grow a first AlGaN gradient layer with gradient aluminum components as the first barrier layer 141 with a thickness range of 3-15 nm by changing temperature to 800-900° C. The aluminum components are controlled by the trimethylaluminum input to the reaction chamber, where, the trimethylaluminum flow at starting point is 0, and gradually increases during growth, and aluminum component range at the ending terminal of the first AlGaN gradient layer is 10-30%;

Next, grow a first InGaN quantum well layer 142 by rising temperature to 750-830° C.;

Next, grow a middle barrier layer 143 by rising temperature to 800-900° C.; the first layer 1431 of the middle barrier layer is an aluminum-containing AlGaN layer with thickness of 1-3 nm; the second layer 1432 of the middle barrier layer is a GaN layer with thickness of 1-5 nm and p-type doping by inputting magnesocene; the third layer 1433 of the middle barrier layer is also an aluminum-containing AlGaN layer with thickness of 1-3 nm; the Al component range of the aluminum-containing AlGaN barrier layer is 5-20%;

Repeatedly grow the aforementioned InGaN quantum well layer 142 and the middle barrier layer 143 having a three-layer structure with repetition cycles of 5-15;

Next, after growing the last InGaN quantum well layer 142, grow the last AlGaN barrier layer, with gradual aluminum components as the last barrier layer 144 with thickness range of 3-15 nm by rising temperature to 800-900° C., in which, the starting aluminum component range is 10-30%, and the aluminum component after growth is 0; the aluminum components are controlled by the flow of the trimethylaluminum input into the reaction chamber;

Next, grow a p-type AlGaN electron blocking layer by rising temperature to 800-950° C.;

Next, grow a P-type GaN layer by controlling temperature at 900-1,050° C.;

Next, grow a heavily-doped p-type GaN contact layer (not shown in the light-emitting diode structure in FIG. 1) by controlling temperature at 900-1,050° C., to form an epitaxial structure of light-emitting diode for improving light-emitting efficiency under high temperature.

Although specific embodiments have been described above in detail, the description is merely for purposes of illustration. It should be appreciated, therefore, that many aspects described above are not intended as required or essential elements unless explicitly stated otherwise. Various modifications of, and equivalent acts corresponding to, the disclosed aspects of the exemplary embodiments, in addition to those described above, can be made by a person of ordinary skill in the art, having the benefit of the present disclosure, without departing from the spirit and scope of the disclosure defined in the following claims, the scope of which is to be accorded the broadest interpretation so as to encompass such modifications and equivalent structures.

1. A light-emitting diode, comprising:
a Type I semiconductor layer;
a Type II semiconductor layer; and
an active layer between the both;
wherein, the active layer is a multi-quantum well structure alternatively composed of well layers and barrier layers, in which, the first barrier layer is a first AlGaN gradient layer of which aluminum components gradually increase in the direction from the Type I semiconductor layer to the quantum well, and the barrier layer at the middle of well layers is an AlGaN/GaN/AlGaN multi-layer barrier layer, and the last barrier layer is a second AlGaN gradient layer of which aluminum components gradually decrease in the direction from the quantum well to the Type II semiconductor layer.

2. The light-emitting diode of claim 1, wherein: the GaN layer of the AlGaN/GaN/AlGaN multi-layer barrier layer is 1-5 nm thick with p-type doping.

3. The light-emitting diode of claim 1, wherein: the GaN layer of the AlGaN/GaN/AlGaN multi-layer barrier layer is p-type doped with doping concentration of 5E17-1E19 cm⁻³.

4. The light-emitting diode of claim 1, wherein: in the AlGaN/GaN/AlGaN multi-layer barrier layer, the AlGaN layer is 1-3 nm thick with Al component range of 5-20%.

5. The light-emitting diode of claim 1, wherein: in the AlGaN/GaN/AlGaN multi-layer barrier layer, the AlGaN layer is 1-3 nm thick with Al component range of 5-20%, and the GaN layer is 1-5 nm thick with p-type doping.

6. The light-emitting diode of claim 1, wherein: the first AlGaN gradient layer is 3-15 nm thick, with Al component of 0 at the starting terminal, and Al component of 10-30% at the ending terminal.

7. The light-emitting diode of claim 1, wherein: the second AlGaN gradient layer is 3-15 nm thick, with aluminum component of 10-30% at the starting terminal, and aluminum component of 0 at the ending terminal.

8. A light-emitting diode fabrication method, comprising growth of a Type I semiconductor layer, an active layer and a Type II semiconductor layer, wherein the active layer is formed by the following steps:
1) growing a first AlGaN gradient layer with gradient aluminum components as the first barrier layer, whose aluminum components are controlled by the trimethylaluminum input to the reaction chamber, where, the trimethylaluminum flow at starting point is 0, and gradually increases during growth;
2) growing a first quantum well layer;
3) growing a middle barrier layer, with a structure of AlGaN/GaN/AlGaN multi-layer barrier layer;
4) repeatedly growing the aforementioned quantum well layer and the middle barrier layer with n cycles, wherein n>2; and
5) growing a second AlGaN gradient layer with gradient aluminum components as the last barrier layer after growing the last quantum well layer, whose aluminum components are controlled by trimethylaluminum flow input into the reaction chamber, wherein, the trimethylaluminum flow is maximum at the starting point, and gradually decreases during growth.

9. The method of claim 8, wherein: the first AlGaN gradient layer formed in step 1) is 3-15 nm thick, with aluminum component of 0 at the starting terminal, and aluminum component of 10-30% at the ending terminal.

10. The method of claim 8, wherein: in the AlGaN/GaN/AlGaN multi-layer barrier layer, the AlGaN layer is 1-3 nm thick with Al component range of 5-20%.

11. The method of claim 8, wherein: in the AlGaN/GaN/AlGaN multi-layer barrier layer formed in step 3), the GaN layer is p-type doped.

12. The method of claim 8, wherein: in the AlGaN/GaN/AlGaN multi-layer barrier layer formed in step 3), the AlGaN layer is 1-3 nm thick with Al component range of 5-20%, and the GaN layer is 1-5 nm thick with p-type doping.

13. The method of claim 8, wherein: the second AlGaN gradient layer formed in step 5) is 3-15 nm thick, with aluminum component of 10-30% at the starting terminal, and aluminum component of 0 at the ending terminal.

14. A light-emitting system comprising a plurality of light-emitting diodes (LEDs), each LED comprising:
a Type I semiconductor layer;
a Type II semiconductor layer; and
an active layer between the both;
wherein, the active layer is a multi-quantum well structure alternatively composed of well layers and barrier layers, in which, the first barrier layer is a first AlGaN gradient layer in which aluminum components gradually increase in the direction from the Type I semiconductor layer to the quantum well, and the barrier layer at the middle of well layers is an AlGaN/GaN/AlGaN multi-layer barrier layer, and the last barrier layer is a second AlGaN gradient layer in which aluminum components gradually decrease in the direction from the quantum well to the Type II semiconductor layer.

15. The system of claim 14, wherein: the GaN layer of the AlGaN/GaN/AlGaN multi-layer barrier layer is 1-5 nm thick with p-type doping.

16. The system of claim 14, wherein: the GaN layer of the AlGaN/GaN/AlGaN multi-layer barrier layer is p-type doped, with doping concentration of 5E17-1E19 cm⁻³.

17. The system of claim 1, wherein: in the AlGaN/GaN/AlGaN multi-layer barrier layer, the AlGaN layer is 1-3 nm thick with Al component range of 5-20%.

18. The system of claim 14, wherein: in the AlGaN/GaN/AlGaN multi-layer barrier layer, the AlGaN layer is 1-3 nm thick with Al component range of 5-20%, and the GaN layer is 1-5 nm thick with p-type doping.

19. The system of claim 14, wherein: the first AlGaN gradient layer is 3-15 nm thick, with Al component of 0 at the starting terminal, and Al component of 10-30% at the ending terminal.

20. The system of claim 14, wherein: the second AlGaN gradient layer is 3-15 nm thick, with aluminum component of 10-30% at the starting terminal, and aluminum component of 0 at the ending terminal.
